(19) United States
(12) Patent Application Publication
(10) Pub. No.: US 2005/0270853 A1
(43) Pub. Date: Dec. 8, 2005

(54) Memory module and method for accessing the same

(76) Inventors: Kevin Chiang, Taipei City (TW); Chih-Chen Tsai, Kao Hsiung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/860,142

(22) Filed: Jun. 4, 2004

(51) Int. Cl. G11C 5/00

(52) U.S. Cl. 365/189.05

(57) ABSTRACT

A memory module and a method for accessing the same are proposed. The memory module comprises a memory, a transmission selection port connected to input of the memory, a first data output port and a second data output port connected to output of the memory. The transmission selection port input one of a first address signal and a second address signal to the memory according to a logical level of a first clock signal. The first data output port and the second data output port access data of memory designated by the first address signal or the second address signal according to the logical level of the first clock signal.

### FIELD OF THE INVENTION

The present invention relates to a memory module and a method for accessing the same, especially to a memory module with single-port memory unit and a method for accessing the same

### BACKGROUND OF THE INVENTION

The memory can be generally classified into read only memory (ROM) and random access memory (RAM) depending on data retention state after power off. More particularly, ROM can permanently or semi-permanently hold data after power is off and is often used to store system program. Therefore, ROM is generally referred as program memory. On the contrary, the data stored in RAM will be lost after power off. Therefore, RAM is used for temporarily storing data and referred as data memory.

The current design trend for ASIC is system on chip (SOC) architecture with built-in memory therein. The built-in memory, for example, can be an SRAM. The start-up instruction of the SOC device is generally stored in an external program memory and is temporarily stored in the built-in SRAM. However, the built-in SRAM in the SOC device can only be used to store program file such that the data file should be stored in external data memory. As a result, the capability of the built-in SRAM cannot be optimally exploited.

### SUMMARY OF THE INVENTION

It is the object of the present invention to provide a memory module with single-port memory unit and having time-sharing accessing scheme and a method for accessing the same.

To achieve the above object, the present invention provides a memory module comprising: a memory; a transmission selection port connected to the memory and sending one of a first address signal and a second address signal to the memory according to a logical level of a first clock signal; a first data output port connected to the memory and outputting a data at an address of the memory designated by the first address signal; and a second data output port connected to the memory and outputting a data at an address of the memory designated by the second address signal.

To achieve the above object, the present invention provides a memory module comprising: a memory; a first input port connected to the memory and sending one of input signals according to a logical level of a first clock signal;
a second input port connected to the memory and sending one of input signals according to the logical level of the first clock signal; a first data output port connected to the memory and reading the memory according to a first logical level of the first clock signal; and a second data output port connected to the memory and reading the memory according to a second logical level of the first clock signal.

To achieve the above object, the present invention provides a method for accessing a memory module with following steps: providing a first clock signal; selecting one of a first address signal and a second address signal to the memory according to a logical level of a first clock signal; selecting one of a first read/write control signal and a second read/write control signal according to the logical level of the first clock signal; the memory receiving the first address signal and the first read/write control signal or the second address signal and second read/write control signal according to the logical level of the first clock signal.

### BRIEF DESCRIPTION OF DRAWINGS

FIG. 1 shows the schematic diagram of a memory module according to the present invention;

FIG. 2 shows the timing diagram of first clock signal and the memory clock; and

FIG. 3 shows the flowchart of the memory accessing method according to the present invention.

### DETAILED DESCRIPTION OF THE INVENTION

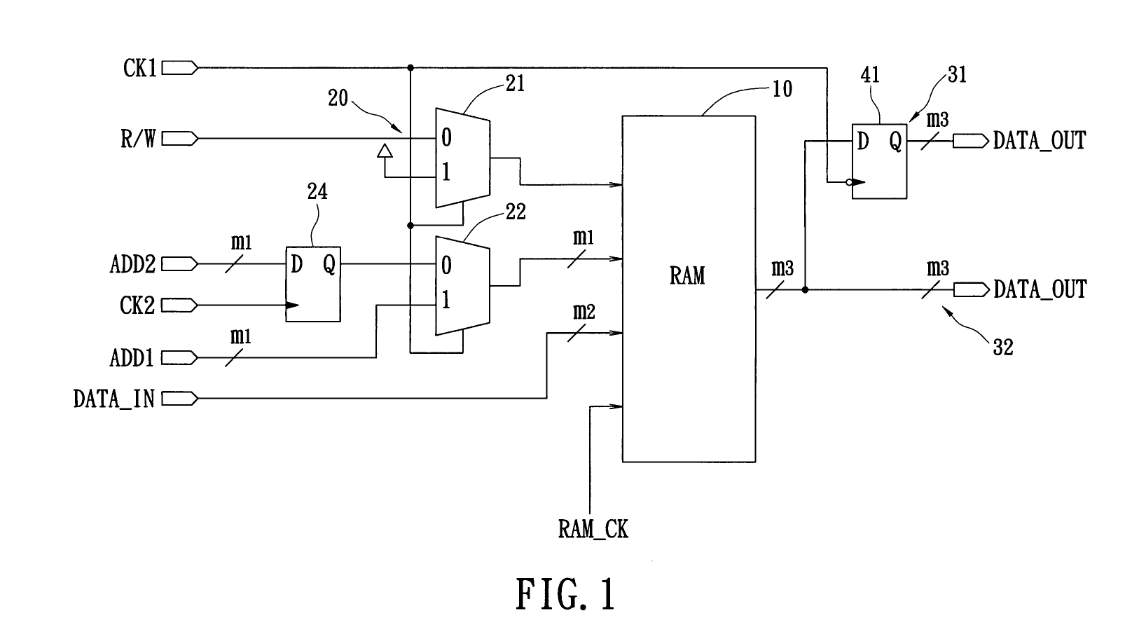

FIG. 1 shows the schematic diagram of a memory module according to the present invention. The memory module comprises a single-port memory unit 10, a transmission selection port 20, a first data output port 31 and a second data output port 32. The transmission selection port 20 is used to select an input signal for accessing the memory unit 10 and is controlled by a first clock signal (CK1). The input signals can be, for example but not limited to, read/write control signal (R/W), first address signal (ADD1), second address signal (ADD2), data input signal (DATA_IN) and are sent to the memory unit 10 in a time-sharing way controlled by the transmission selection port 20. The first data output port 31 and the second data output port 32 are both connected to the output of the memory unit 10 and functioned to access data stored in the memory unit 10 in response to the first address signal (ADD1) and second address signal (ADD2), respectively. In this shown embodiment, the first address signal (ADD1) is used to read data stored in the memory unit 10. For example, the data stored in the memory unit 10 can be start-up instruction. The second address signal (ADD2) is used to write data into the memory unit 10.

The transmission selection port 20 comprises a first input port 21 and a second input port 22, both of which are multiplexer with two input ends. The signals at the two input ends are selected by the first clock signal (CK1) such that one of them is output to the input end of the memory unit 10. More particularly, the D0 input end of the first input port 21 is connected to the read/write control signal (R/W) and the D1 input end of the first input port 21 is connected to a logical-one high level. The D0 input end of the second input port 22 is connected to the second address signal (ADD2) through a data latch 24 and the D1 input end of the second input port 22 is connected to the first address signal (ADD1). The data latch 24 is a D-type flip-flop and functioned to latch the second address signal (ADD2) for the second input port 22. The data input signal (DATA_IN) is directly connected to the input of the memory unit 10 to send writing data to the memory unit 10.

When the first clock signal (CK1) is at logical-zero low level, the first input port 21 outputs the read/write control signal (R/W) and the second input port 22 outputs the second address signal (ADD2). Moreover, when read/write control signal (R/W) is at logical-zero low level, the data input signal (DATA_IN) is written to the memory unit 10 in the address designated by the second address signal (ADD2). When read/write control signal (R/W) is at logical-one high level, the data in address designated by the second address signal (ADD2) is read from the memory unit 10. When the first clock signal (CK1) is at logical-one high level, the first input port 21 outputs a logical-one high level and the second input port 22 outputs the first address signal (ADD1). At this time, the memory unit 10 is read only with the address designated by the first address signal (ADD1).

To render dual-port accessing ability to the single-port memory unit 10, the input ends of the first data output port 31 and the second data output port 32 are connected to the output of the memory unit 10. The first data output port 31 is connected to the memory unit 10 through a data latch 41 for latching the output data of the memory unit 10. The first data output port 31 and the second data output port 32 output data sent from the memory unit 10 in a time-sharing manner. The data latch 41 is a D-type flip-flop with negative edge triggering and clocked by the first clock signal (CK1). The first address signal (ADD1) and the second address signal (ADD2) are input to the memory unit 10 in a time-sharing manner controlled by the logical level of the first clock signal (CK1). The first data output port 31 and the second data output port 32 will read the data at address designated by the first address signal (ADD1) and the second address signal (ADD2), respectively, in time-sharing manner.

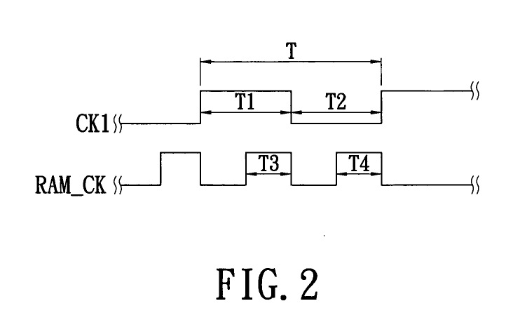

With reference now to FIG. 2, the memory unit 10 uses a memory clock (RAM_CLK) from the same clock source as the first clock signal (CK1) and clocked at double frequency to the first clock signal (CK1). Therefore, the memory unit 10 will be accessed twice during single period T of the first clock signal (CK1). In other word, the memory unit 10 is read during the duration T3 of the memory clock (RAM_CLK) when the first clock signal (CK1) is at logical high level (T1). The memory unit 10 is accessed during the duration T4 of the memory clock (RAM_CLK) when the first clock signal (CK1) is at logical low level (T2). The second clock signal (CK2) has same frequency as the first clock signal (CK1) and phase shift between the second clock signal (CK2) and the first clock signal (CK1) is also allowable.

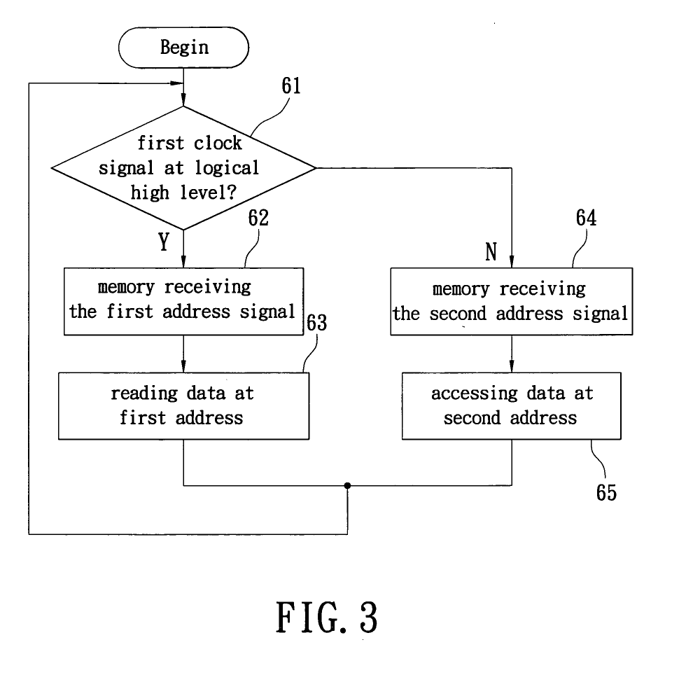

FIG. 3 depicts the flowchart of the memory accessing method according to the present invention, wherein the hardware shown in FIG. 1 is operated according to the timing shown in FIG. 2. The method comprises following steps:

Step 61: The transmission selection port 20 judging whether the first clock signal (CK1) is logical high level?

If true, the procedure jumps to a step 62; else the procedure jumps to a step 64;

Step 62: The memory unit 10 receives the first address signal (ADD1) and is operated at a program reading state.

Step 63: The data of the memory unit 10 at the first address signal (ADD1) is read and output from the first data output port 31. At this time, the first input port 21 outputs a logical-one high level to the memory unit 10.

Step 64: The memory unit 10 receives the second address signal (ADD2) and is operated at a data accessing state.

Step 65: The data of the memory unit 10 at the second address signal (ADD2) is accessed and the accessing is controlled by the read/write control signal (R/W) input from the D0 end of the first input port 21. When the read/write control signal (R/W) is at logical high level, the data at address designated by the second address signal (ADD2) is read and output from the second data output port 32. When the read/write control signal (R/W) is at logical low level, the data input signal (DATA_IN) is written to the memory unit 10 in the address designated by the second address signal (ADD2).

The memory module according to the present invention accesses the memory unit 10 in a time-sharing manner according to the logical level of the first clock signal (CK1). The first input port 21 and the second input port 22 will select one of input data thereof for sending to the memory unit 10 according to the logical level of the first clock signal (CK1). The first data output port 31 and the second data output port 32 output data sent from the first input port 21 and the second input port 22 in a time-sharing manner according to the logical level of the first clock signal (CK1). In above-mentioned preferred embodiment, the first address signal (ADD1) is used to read program stored in the memory unit 10 for booting SOC device. The second address signal (ADD2) indicates the accessible area in the memory unit 10. Therefore, an SOC device can both read program from and access data to the same memory unit in the memory module according to the present invention.

The first address signal (ADD1) and the second address signal (ADD2) can be designed to simultaneously write data to or read data from memory by setting the read/write control signal (R/W).

To sum up, the memory module according to the present invention has following features:
1. Enabling program reading and data accessing for the same memory.
2. Separating reading time and writing time in a memory by time-sharing scheme to prevent confliction.
3. Realizing dual-port data transmission by a single-port memory unit.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

1. A memory module comprising:
a random access memory;
a transmission selection port connected to the memory and sending one of a first address signal and a second address signal to the memory according to a logical level of a first clock signal;
a first data output port connected to the memory and outputting a data at an address of the memory designated by the first address signal; and
a second data output port connected to the memory and outputting a data at an address of the memory designated by the second address signal.

2. The memory module as in claim 1, wherein the transmission selection port sends the first address signal when the first clock signal is at a first logical level, and the transmission selection port sends the second address signal when the first clock signal is at a second logical level.

3. The memory module as in claim 1, wherein the first data output port is a data latch.

4. The memory module as in claim 4, wherein the data latch is a D-type flip-flop clocked by the first clock signal.

5. A memory module comprising:
a random access memory;
a first input port connected to the memory and sending one of input signals according to a logical level of a first clock signal;
a second input port connected to the memory and sending one of input signals according to the logical level of the first clock signal;
a first data output port connected to the memory and reading the memory according to a first logical level of the first clock signal; and
a second data output port connected to the memory and reading the memory according to a second logical level of the first clock signal.

6. The memory module as in claim 5, wherein the first input port and the second input port are multiplexer controlled by the first clock signal.

7. The memory module as in claim 6, wherein the multiplexer has two input ends.

8. The memory module as in claim 5, wherein the first data output port is a datalatch.

9. The memory module as in claim 8, wherein the data latch is a D-type flip-flop clocked by the first clock signal.

10. A method for accessing a memory module, which is used to control accessing of a memory and has following steps:
providing a first clock signal;
selecting one of a first address signal and a second address signal to the memory according to a logical level of a first clock signal;
selecting one of a first read/write control signal and a second read/write control signal according to the logical level of the first clock signal;
the memory receiving the first address signal and the first read/write control signal or the second address signal and second read/write control signal according to the logical level of the first clock signal.

11. The method for accessing a memory module as in claim 10, wherein the first address signal and the first read/write control signal are sent to the memory when the first clock signal is at a first logical level.

12. The method for accessing a memory module as in claim 10, wherein the second address signal and the second read/write control signal are sent to the memory when the first clock signal is at a second logical level.

13. The method for accessing a memory module as in claim 10, further comprising a step of inputting data signal to the memory.

14. The method for accessing a memory module as in claim 10, further comprising a step of outputting data of memory designated by the first address signal or outputting data of memory designated by the second address signal according to the logical level of the first clock signal.

15. The method for accessing a memory module as in claim 10, wherein the memory has a working clock being double frequency of the first clock signal.
